(19) United States
(12) Patent Application Publication
(10) Pub. No.: US 2024/0310821 A1
(43) Pub. Date: Sep. 19, 2024

(54) DIAGNOSTIC APPARATUS AND DIAGNOSTIC METHOD, AND SEMICONDUCTOR MANUFACTURING APPARATUS SYSTEM AND SEMICONDUCTOR APPARATUS MANUFACTURING SYSTEM

(71) Applicant: Hitachi High-Tech Corporation, Minato-ku, Tokyo (JP)

(72) Inventors: Masaaki YAMAMOTO, Tokyo (JP); Ryoji ASAKURA, Tokyo (JP); Masahiro SUMIYA, Tokyo (JP); Yohei KAWAGUCHI, Tokyo (JP)

(21) Appl. No.: 18/026,071

(22) PCT Filed: Feb. 24, 2022
(86) PCT No.: PCT/JP2022/007541

§ 371 Date: Mar. 13, 2023

(51) Int. Cl. G05B 23/02

(52) U.S. Cl. CPC G05B 23/0221

(57) ABSTRACT

An apparatus diagnostic apparatus is configured such that: a time range during which a first time-series signal obtained from a sensor is masked is set; data in which a first time-series signal corresponding to the masked time range is masked is created; a standardized model is created by using the data obtained by masking the first time-series signal; a standardization process is performed on the data in which the first time-series signal is masked by using the standardized model; a normal model is created by using a plurality of pieces of data; masking of a second time-series signal in a masked time range is performed on a second time-series signal obtained from a sensor; a standardization process is performed by using the standardized model; and an anomalous value is calculated from a signal obtained by the standardization process of the second time-series signal.

### TECHNICAL FIELD

The present invention relates to a diagnostic apparatus and a diagnostic method, and a semiconductor manufacturing apparatus system and a semiconductor apparatus manufacturing system.

### BACKGROUND ART

Maintenance of plasma treatment apparatuses that perform processing of semiconductor wafers typically include internal cleaning and component replacement that are performed regularly, depending on the number of processed wafers and the like. However, due to ageing of components included in the plasma treatment apparatuses and use methods thereof, unexpected downtime occurs undesirably in some cases.

It is considered that, in order to reduce this unexpected downtime, it is effective to adopt a method in which the states of deterioration of components or a plasma treatment apparatus are monitored, and maintenance (cleaning or replacement) of components or the like is performed in accordance with the states of deterioration.

PTL 1 describes an anomaly sensing system including an extracting section that extracts a particular anomaly-sensing-subject subsequence in a plurality of subsequences from a composite sequence included in a monitoring signal. In configuration of the anomaly sensing system, the extracting section determines an optimal warping path by dynamic time warping from the composite sequence and a pre-acquired reference sequence which is an example of composite sequences, the extracting section identifies the start point and end point of a particular subsequence on the basis of the optimal warping path and the start point and end point of a subsequence of the pre-acquired reference sequence, and the extracting section extracts a particular subsequence on the basis of the start point and end point of the particular subsequence. The anomaly sensing system enables easy extraction of an interval signal of a particular sub-step.

### CITATION LIST

### Patent Literature

PTL 1: Japanese Patent Application Laid-Open No. 2020-204832

### SUMMARY OF INVENTION

### Technical Problem

The timings of a rise and a fall of a signal obtained by monitoring the state of a plasma treatment apparatus can change a little due to variations of the state in the midst of operation of the plasma treatment apparatus. In such a case, the values of times of the rise and the fall of the signal differ significantly from values of an expected value signal undesirably, in some cases.

As a result, errors between the sensing-subject signal and the expected value signal exceed a tolerance range, and it becomes impossible to accurately detect the subsequence undesirably, in some cases, but, in such a case, it may be erroneously determined by the method described in PTL 1 that there is an anomaly in the apparatus state, undesirably.

The present invention solves problems of the conventional technology like the one described above, and provides a diagnostic apparatus and a diagnostic method, and a semiconductor manufacturing apparatus system and a semiconductor apparatus manufacturing system that enable sensing of an anomaly of an apparatus state even in a case that a rise and a fall of a monitoring signal corresponding to the start and end of each subsequence could not be extracted accurately.

### Solution to Problem

In order to solve the problem described above, in configuration according to the present invention, a diagnostic apparatus makes a diagnosis of a state of a semiconductor manufacturing apparatus by using first time-series data acquired from a sensor group of the semiconductor manufacturing apparatus, in which a masking period including a rising time of the first time-series data or a falling time of the first time-series data is determined, the first time-series data of the determined masking period is converted into a predetermined value, and also the converted first time-series data is output as second time-series data, and the diagnosis of the state of the semiconductor manufacturing apparatus is made on the basis of the second time-series data.

In addition, in order to solve the problem described above, in configuration according to the present invention, a diagnostic apparatus makes a diagnosis of a state of a semiconductor manufacturing apparatus by using first time-series data acquired from a sensor group of the semiconductor manufacturing apparatus, in which a masking period including a rising time of the first time-series data or a falling time of the first time-series data is determined, the first time-series data of the determined masking period is converted into a predetermined value, and also a feature quantity of the masking period is determined, the converted first time-series data is output as second time-series data, the determined feature quantity is added to the second time-series data, and the diagnosis of the state of the semiconductor manufacturing apparatus is made on the basis of the second time-series data to which the feature quantity is added.

Furthermore, in order to solve the problem described above, in configuration according to the present invention, a semiconductor apparatus manufacturing system includes a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network, in which the application executes: a step at which a masking period including a rising time of the first time-series data or a falling time of the first time-series data is determined; a step at which the first time-series data of the determined masking period is converted into a predetermined value, and also the converted first time-series data is output as second time-series data; and a step at which the diagnosis of the state of the semiconductor manufacturing apparatus is made on the basis of the second time-series data.

Furthermore, in order to solve the problem described above, in configuration according to the present invention, a semiconductor apparatus manufacturing system includes a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network, in which the application executes: a step at which a masking period including a rising time of the first time-series data or a falling time of the first time-series data is determined; a step at which the first time-series data of the determined masking period is converted into a predetermined value, and also a feature quantity of the masking period is determined; a step at which the converted first time-series data is output as second time-series data; a step at which the determined feature quantity is added to the second time-series data; and a step at which the diagnosis of the state of the semiconductor manufacturing apparatus is made on the basis of the second time-series data to which the feature quantity is added.

Furthermore, in order to solve the problem described above, in configuration according to the present invention, a semiconductor apparatus manufacturing system includes a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network, in which the application executes: a step at which a masking period including a rising time of the first time-series data or a falling time of the first time-series data is determined; a step at which the first time-series data of the determined masking period is converted into a predetermined value, and also a feature quantity of the masking period is determined; and a step at which the diagnosis of the state of the semiconductor manufacturing apparatus is made on the basis of the feature quantity.

Furthermore, in order to solve the problem described above, in configuration according to the present invention, a diagnostic method of making a diagnosis of a state of a semiconductor manufacturing apparatus by using first time-series data acquired from a sensor group of the semiconductor manufacturing apparatus includes: a step at which a masking period including a rising time of the first time-series data or a falling time of the first time-series data is determined; a step at which the first time-series data of the determined masking period is converted into a predetermined value, and also the converted first time-series data is output as second time-series data; and a step at which the diagnosis of the state of the semiconductor manufacturing apparatus is made on the basis of the second time-series data.

Furthermore, in order to solve the problem described above, in configuration according to the present invention, a diagnostic method of making a diagnosis of a state of a semiconductor manufacturing apparatus by using first time-series data acquired from a sensor group of the semiconductor manufacturing apparatus includes: a step at which a masking period including a rising time of the first time-series data or a falling time of the first time-series data is determined; a step at which the first time-series data of the determined masking period is converted into a predetermined value, and also a feature quantity of the masking period is determined; a step at which the converted first time-series data is output as second time-series data; a step at which the determined feature quantity is added to the second time-series data; and a step at which the diagnosis of the state of the semiconductor manufacturing apparatus is made on the basis of the second time-series data to which the feature quantity is added.

### Advantageous Effects of Invention

According to the present invention, the masking period creating section and the masking section can eliminate a significant anomalous value caused by a rising time of a sensing-subject signal. Then, it becomes possible to sense an anomaly of the apparatus state even in a case that each subsequence could not be extracted accurately.

In addition, according to the present invention, the masking period creating section can remove the complexity of manually defining masking periods.

### BRIEF DESCRIPTION OF DRAWINGS

FIG. 1 is a block diagram depicting the basic configuration of an apparatus diagnostic apparatus according to Example 1 of the present invention.

FIG. 2 is a block diagram depicting the basic configuration of a semiconductor manufacturing system according to Example 1 of the present invention.

FIG. 3 is a block diagram depicting the configuration of systems each having a different functionality in the apparatus diagnostic apparatus according to Example 1 of the present invention.

FIG. 4 is a flowchart depicting a procedure of processing at a learning phase in the apparatus diagnostic apparatus according to Example 1 of the present invention.

FIG. 5A is a graph depicting an example of normal signal waveform data.

FIG. 5B is a graph depicting a signal rising portion and falling portion in the normal waveform data that are to be masked.

FIG. 5C is a graph depicting an example after the masking of the signal rising portion and falling portion in the normal waveform data.

FIG. 5D is a graph depicting an example after normalization of the normal waveform data whose signal rising portion and falling portion are masked.

FIG. 6 is a flowchart depicting a procedure of processing at an evaluation phase in the apparatus diagnostic apparatus according to Example 1 of the present invention.

FIG. 7 is a flowchart depicting a procedure of processing at a masking period creating section in the apparatus diagnostic apparatus according to Example 1 of the present invention.

FIG. 8 is a graph depicting sensor-value time-series data obtained from sensors mounted on the semiconductor manufacturing system.

FIG. 9 is a table depicting a masking start time and a masking end time that are created at the masking period creating section in the apparatus diagnostic apparatus according to Example 1 of the present invention.

FIG. 10 is a graph depicting sensor-value time-series data in a state that masks are applied to periods depicted in FIG. 9 in the time-series data in FIG. 8.

FIG. 11 is a block diagram depicting the basic configuration of an apparatus diagnostic apparatus according to Example 2 of the present invention.

FIG. 12 is a block diagram depicting the configuration of a learning system in the apparatus diagnostic apparatus according to Example 2 of the present invention.

FIG. 13 is a block diagram depicting the configuration of an evaluation system in the apparatus diagnostic apparatus according to Example 2 of the present invention.

FIG. 14 is a flowchart depicting a procedure of processing at a learning phase in the apparatus diagnostic apparatus according to Example 2 of the present invention.

FIG. 15 is a flowchart depicting a procedure of processing at an evaluation phase in the apparatus diagnostic apparatus according to Example 2 of the present invention.

FIG. 16 is a flowchart depicting a procedure of processing at a feature quantity generating section and a feature quantity adding section in the apparatus diagnostic apparatus according to Example 2 of the present invention.

FIG. 17 is a block diagram depicting the basic configuration of an apparatus diagnostic apparatus according to Example 3 of the present invention.

FIG. 18 is a block diagram depicting the configuration of a learning system in the apparatus diagnostic apparatus according to Example 3 of the present invention.

FIG. 19 is a flowchart of a step at which a normal model is created at a learning system in the apparatus diagnostic apparatus according to Example 3 of the present invention.

FIG. 20 is a flowchart depicting a procedure of processing at an evaluation phase in the apparatus diagnostic apparatus according to Example 3 of the present invention.

FIG. 21 is a flowchart depicting a procedure of processes of calculating a masking period at a masking period creating section in the apparatus diagnostic apparatus according to Example 3 of the present invention.

FIG. 22 is a flowchart depicting a procedure of processing at the apparatus diagnostic apparatus according to Example 4 of the present invention.

### DESCRIPTION OF EMBODIMENTS

The present invention relates to an apparatus diagnostic apparatus that senses an anomaly of an apparatus on the basis of first time-series data acquired from a sensor group that monitors the state of the apparatus, and to a semiconductor manufacturing system including the apparatus diagnostic apparatus. The apparatus diagnostic apparatus includes: a masking period creating section that calculates a masking period for the first time-series data from information about a rising period or a falling period of the first time-series data; a masking section that changes the first time-series data in the masking period into a predefined value, and outputs the changed first time-series data as second time-series data; and an anomalous value calculating section that outputs, as an anomalous value, a portion where there is a large difference between second time-series data that is observed in a case that the apparatus is normal and evaluation-subject second time-series data that is observed in a case that it is unknown whether the apparatus is normal or anomalous.

In addition, according to the present invention, the apparatus diagnostic apparatus includes a masking period creating section that calculates a masking period in which some of time-series data is masked, from information about a rising period or a falling period of the time-series data, and an apparatus diagnosis is made by using information about time-series data in the masking period and/or information about the apparatus obtained in a time range in which masking is not performed.

Embodiments of the present invention will be explained below in detail on the basis of the figures. Through all the figures for explaining the present embodiments, elements having identical functionalities are given identical reference characters, and repetitive explanations thereof are omitted in principle.

It should be noted that interpretation of the present invention is not limited by the description content of the embodiments depicted below. It is easily understood by those skilled in the art that the specific configuration of the present invention can be changed within the scope not departing from the idea or aim of the present invention.

### Example 1

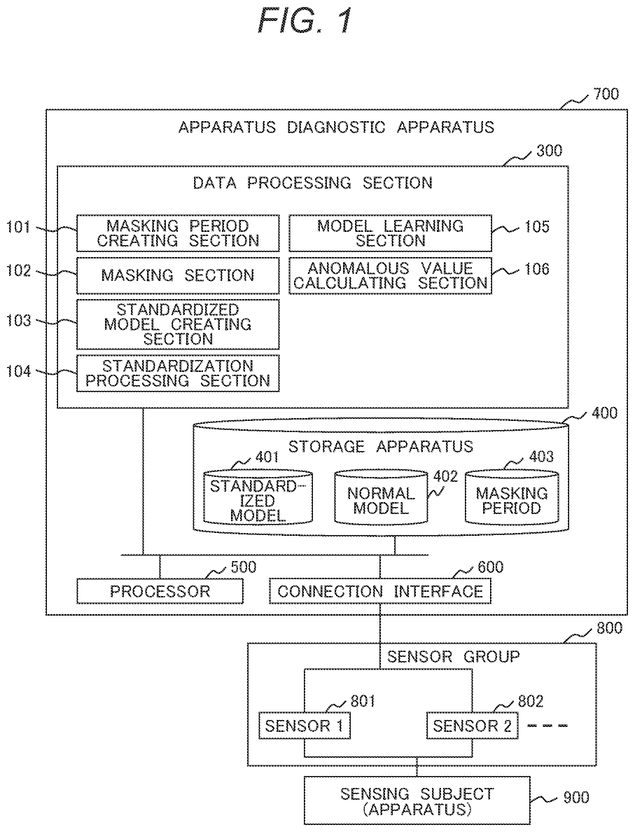

FIG. 1 depicts the relationship between an apparatus diagnostic apparatus 700, and a sensing subject (apparatus) 900 and a sensor group 800 according to Example 1 of the present invention.

The apparatus diagnostic apparatus 700 according to the present example processes signals obtained from the sensor group 800 including a plurality of sensors such as a sensor 1:801 (e.g., a voltage sensor), a sensor 2:802 (e.g., a pressure sensor), . . . and the like mounted on the sensing subject (apparatus) 900 such as a semiconductor manufacturing apparatus, and makes a diagnosis of the state of the sensing subject (apparatus) 900 such as the semiconductor manufacturing apparatus.

The apparatus diagnostic apparatus 700 includes: a connection interface 600 that receives signals output from the sensor group 800; a data processing section 300 that processes the signals output from the sensor group 800, and input via the connection interface 600; a storage apparatus 400 that stores data processed at the data processing section 300; and a processor 500 that controls processes on data at the data processing section 300, the storage apparatus 400, and the connection interface 600.

The data processing section 300 includes a masking period creating section 101, a masking section 102, a standardized model creating section 103, a standardization processing section 104, a model learning section 105, and an anomalous value calculating section 106.

The storage apparatus 400 includes: a standardized model storage section 401 that stores a standardized model created at the standardized model creating section 103 of the data processing section 300; a normal model storage section 402 that stores a normal model created at the model learning section 105; and a masking period storage section 403 that stores a masking start time and a masking period created at the masking period creating section 101.

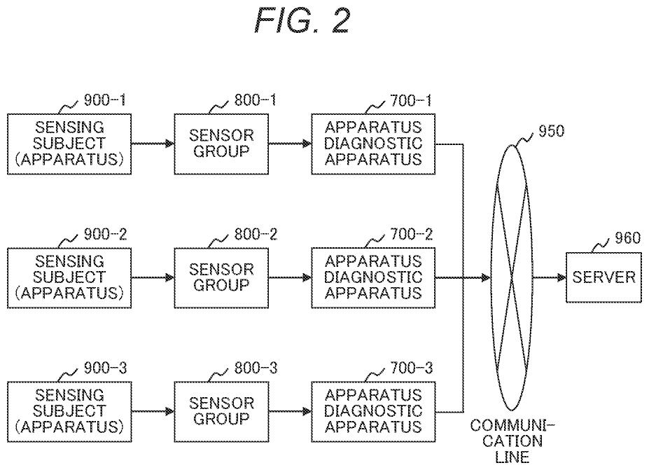

FIG. 2 depicts configuration in which sensing subjects (apparatuses) 900-1, 900-2, and 900-3 corresponding to the sensing subject (apparatus) 900, sensor groups 800-1, 800-2, and 800-3 corresponding to the sensor group 800, and apparatus diagnostic apparatuses 700-1, 700-2, and 700-3 corresponding to the apparatus diagnostic apparatus 700, that are explained in FIG. 1, are connected with a server 960 via a communication line 950.

A diagnosis of the apparatus state of the sensing subject (apparatus) 900-1 is made by the apparatus diagnostic apparatus 700-1 processing detection signals obtained from the sensor group 800-1 mounted on the sensing subject (apparatus) 900-1 such as a semiconductor manufacturing apparatus, and a result of the diagnosis is sent to the server 960 via the communication line 950, and stored thereon. Data obtained from the sensor groups 800-2 and 800-3 mounted on the sensing subjects (apparatuses) 900-2 and 900-3 is similarly processed at the apparatus diagnostic apparatuses 700-2 and 700-3, and is sent to the server 960 via the communication line 950, and stored thereon.

Note that instead of the configuration depicted in FIG. 2, the apparatus diagnostic apparatuses 700-1, 700-2, and 700-3 corresponding to the apparatus diagnostic apparatus 700 may be arranged between the communication line 950 and the server 960, in another possible configuration.

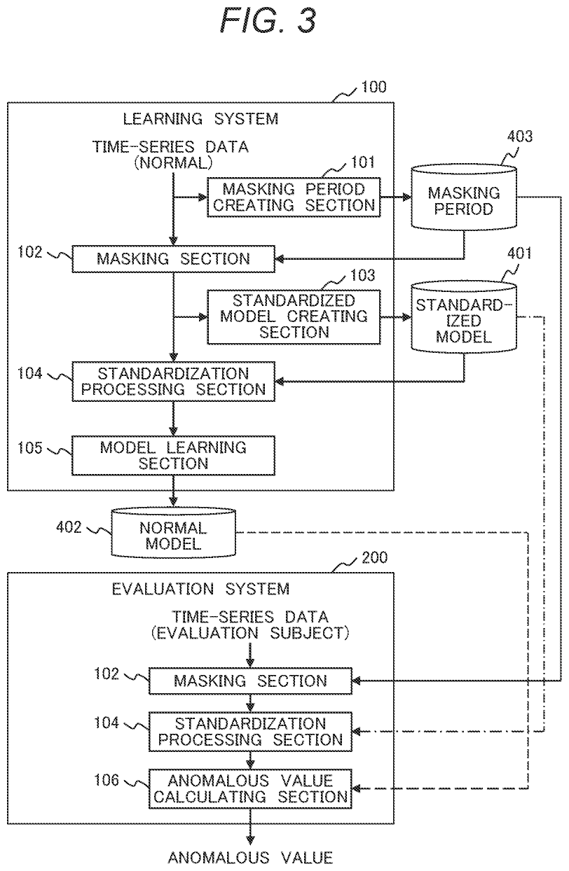

FIG. 3 depicts a block diagram depicting the configuration of systems each having a different functionality in the apparatus diagnostic apparatus 700 according to the present example. Each section included in the data processing section 300 in FIG. 1 is included in either a learning system 100 or an evaluation system 200 depending on data that it processes.

The learning system 100 includes the masking period creating section 101, the masking section 102, the standardized model creating section 103, the standardization processing section 104, and the model learning section 105, and accepts input of time-series data that is input from the sensor group 800 via the connection interface 600, and is obtained when the sensing subject (apparatus) 900 is operating normally.

The masking period creating section 101 sets a masking period for masking part of the input time-series data, and stores it on the masking period storage section 403.

The masking section 102 creates masked data of input normal data 310 on the basis of masking data stored on the masking period storage section 403.

The standardized model creating section 103 creates a standardized model from the data masked at the masking section 102, and stores it on the standardized model storage section 401.

By using the standardized model stored on the standardized model storage section 401, the standardization processing section 104 performs a standardization process on the normal-time time-series data masked at the masking section 102 such that the average becomes 0, and the variance becomes 1, for example.

The model learning section 105 creates a normal model by learning a plurality of pieces of standardized data created at the standardization processing section 104, and stores it on the normal model storage section 402.

Next, the evaluation system 200 includes the masking section 102, the standardization processing section 104, and the anomalous value calculating section 106, and accepts input of time-series data that is input from the sensor group 800 via the connection interface 600, and is obtained when the sensing subject (apparatus) 900 is operating in an evaluation-subject period.

The masking section 102 performs masking on the input evaluation-subject time-series data by using data of a masking time and a masking period stored on the masking period storage section 403.

By using the standardized model stored on the standardized model storage section 401, the standardization processing section 104 performs a standardization process on the masked time-series data such that the average becomes 0, and the variance becomes 1, for example.

The anomalous value calculating section 106 calculates an anomalous value by comparing the standardized data with the normal model stored on the normal model storage section 402, and outputs the detected anomalous value to an undepicted output section of the apparatus diagnostic apparatus 700 and/or the server 960.

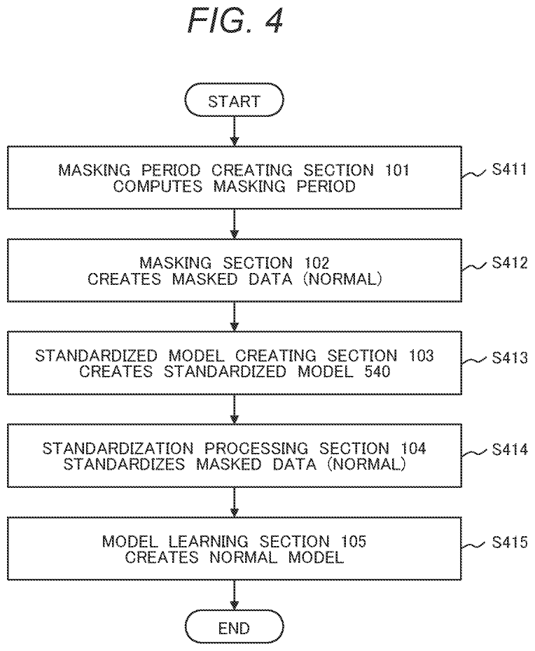

Next, a step of creating the normal model at the learning system 100 will be explained by using FIG. 4.

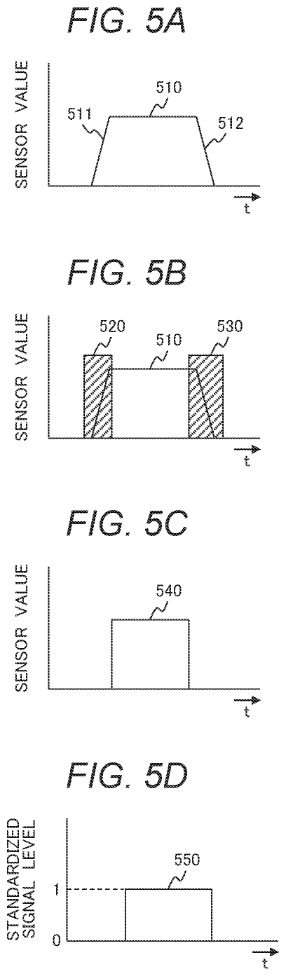

First, the masking period creating section 101 computes masking periods for masking, in periods 520 and 530 as depicted in FIG. 5B, data of the periods of a rise 511 and a fall 512 of a signal in input normal data 510 like that depicted in FIG. 5A, and stores the masking periods on the masking period storage section 403 (S411).

Next, on the basis of the masking data created at the masking period creating section 101 and stored on the masking period storage section 403, the masking section 102 creates data obtained by masking, in the period 520 and the period 530, data of predetermined periods at the rise 511 and the fall 512 of the signal in the input normal data 510 (S412).

Next, the standardized model creating section 103 creates a standardized model 540 like the one depicted in FIG. 5C in which the normal-time time-series data masked at the masking section 102 has levels of the signal in the masked periods that are set to zero levels, for example, and stores it on the standardized model storage section 401 (S413).

Next, by using a standardized model 540 stored on the standardized model storage section 401 and the normal-time time-series data masked at the masking section 102, the standardization processing section 104 performs a standardization process such that the average becomes 0, and the variance becomes 1, for example, creates a pattern 550 with a standardized signal waveform like the one depicted in FIG. 5D, and stores it on the model learning section 105 (S414).

Next, the model learning section 105 learns a pattern with a standardized signal waveform that is obtained when the sensing subject (apparatus) is operating normally, from a plurality of patterns 550 with standardized signal waveforms created from a plurality of pieces of normal time-series data input via the connection interface 600, and stores the pattern on the normal model storage section 402 (S415).

By learning the pattern with the standardized signal waveform that is obtained when the sensing subject (apparatus) is operating normally from the plurality of patterns 550 with the standardized signal waveforms in this manner, it is possible to perform masking surely at the masking section 102 on a rising period and a falling period of a monitoring signal even in a case that a rise and a fall of the monitoring signal corresponding to the start and end of each subsequence could not be extracted accurately.

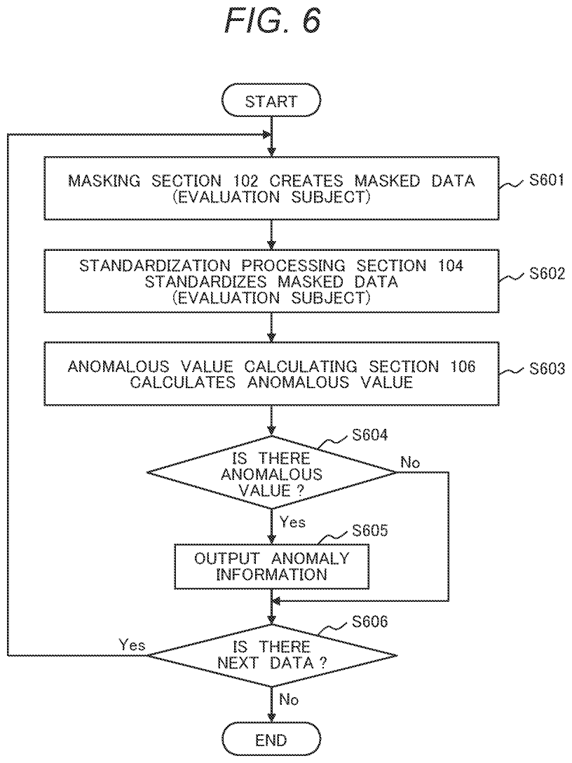

Next, a procedure of processes of detecting an anomaly by the evaluation system 200 processing time-series data that is input from the sensor group 800 via the connection interface 600, and is obtained when the sensing subject (apparatus) 900 is operating in an evaluation-subject period will be explained by using a flowchart in FIG. 6.

First, by using data of a masking period stored on the masking period storage section 403, the masking section 102 performs masking on evaluation-subject time-series data input from the sensor group 800 via the connection interface 600, and creates masked data (evaluation subject) (S601).

Next, by using the standardized model stored on the standardized model storage section 401, the standardization processing section 104 performs a standardization process on the masked data (evaluation subject) created at the masking section 102, and creates standardized data (S602).

Next, the anomalous value calculating section 106 compares the evaluation-subject standardized data created at the standardization processing section 104 at S602 with the normal model stored on the normal model storage section 402, and calculates an anomalous value in the evaluation-subject standardized data (S603).

Next, it is determined whether an anomalous value is calculated at S603 (S604). In a case that an anomalous value is calculated (Yes at S604), information about the anomalous value is output to the undepicted output section in the apparatus diagnostic apparatus 700 and/or the server 960 (S605).

Next, it is checked whether there remains evaluation-subject time-series data (S606), and in a case that there is not evaluation-subject time-series data (No at S606), the series of processing ends. In a case that there is evaluation-subject time-series data (Yes at S606), the procedure returns to S601, and the series of processing is continued.

On the other hand, in a case that an anomalous value is not calculated (No at S604), it is checked whether there remains evaluation-subject time-series data (S606). In a case that there is not evaluation-subject time-series data (No at S606), the series of processing ends, and in a case that there is evaluation-subject time-series data (Yes at S606), the procedure returns to S601, and the series of processing is continued.

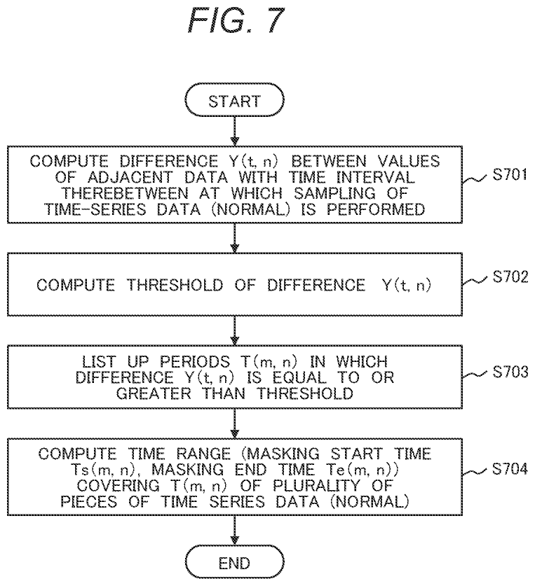

Next, a method of calculating a masking time at the masking period creating section 101 explained regarding S411 in FIG. 4 will be explained by using FIG. 7.

First, time-series data that is input from the sensor group 800 via the connection interface 600, and is obtained when the sensing subject (apparatus) 900 is operating normally is input to the masking period creating section 101, and a difference Y(t, n) between values of data that are adjacent to each other with a time interval therebetween at which sampling of time-series data (normal) is performed is calculated (S701). Here, t is a time, and n is an identifier of each of a plurality of pieces of time series data.

For example, in a case that time-series data like that depicted in FIG. 8 is input, since the time-series data exhibits gradual changes between times t₁ and t₂ corresponding to a rising portion 811 of a signal, and between times t₃ and t₄ corresponding to a falling portion 812 of the signal, the difference Y(t, n) between values of adjacent data has finite values greater than zero. On the other hand, since a signal 810 between the times t₂ and t₃ is almost constant, the difference Y(t, n) between values of adjacent time-series data is zero or a value close to zero.

Next, a threshold of the difference Y(t, n) is computed by using a plurality of pieces of time series data (S702). For example, a value obtained by multiplying the standard deviation σ of a plurality of differences Y(t, n) by N is defined as the threshold. Here, regarding time-series data like that depicted in FIG. 8, the threshold is set to a value greater than the difference Y(t, n) between values of adjacent time-series data in the signal 810 between the times t₂ and t₃, and smaller than the difference Y(t, n) between values of time-series data between the times t₁ and t₂ and between the times t₃ and t₄.

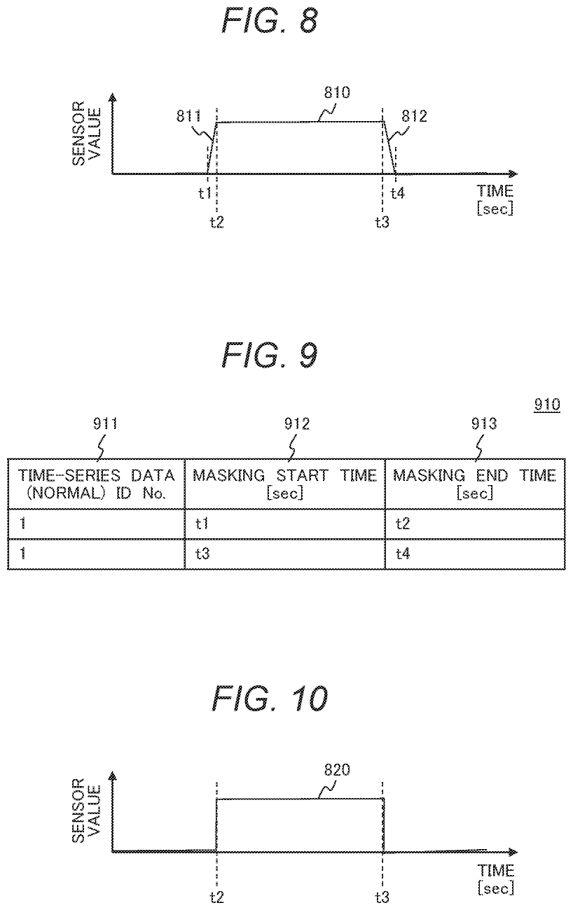

Next, periods T(m, n) in which the difference Y(t, n) calculated at S701 becomes equal to or greater than the threshold set at S702 are listed up (S703). FIG. 9 depicts an example thereof.

A table 910 in FIG. 9 corresponds to the signal pattern in FIG. 8. A time-series data (normal) ID No. 911 corresponds to n in Y(t, n) explained above, a masking start time 912 corresponds to the time t₁ or t₄ in the sensor-value time-series data in FIG. 8, and a masking end time 913 corresponds to the time t₂ or t₄ in the sensor-value time-series data in FIG. 8.

Next, a time range (a masking start time Ts(m, n), and a masking end time Te(m, n)) that covers periods T(m, n) during which the difference Y(t, n) becomes equal to or greater than the threshold that are listed up at S703 is computed (S704). By setting the masking start time Ts(m, n) and the masking end time Te(m, n) such that they cover the periods T(m, n) during which the difference Y(t, n) becomes equal to or greater than the threshold that are listed up at S703 in this manner, it becomes possible to surely mask the time ranges of a rise and a fall of a signal even if time-series data (evaluation subject) includes small variations, and the reliability of monitoring of the apparatus state can be enhanced.

As an example, FIG. 10 depicts a waveform pattern 820 of sensor values that is obtained when masking is performed on the signal pattern in FIG. 8 by using data of the masking start time 912 and the masking end time 913 depicted in the table 910 in FIG. 9. The signal pattern in FIG. 8 is masked in the periods between the times t₁ and t₂, and between the times t₃ and t₄, the signal level in these periods becomes zero, and the waveform pattern 820 having a steep rise and fall is formed.

Finally, information about the masking start time Ts(m, n) and the masking end time Te(m, n) that are determined by the computation at S704 is sent from the masking period creating section 101 to the masking period storage section 403, and the step of computing the masking times at S411 is ended.

Note that here, in a case that the masking start time Ts(m, n) determined by the computation at S704 is earlier than a masking end time Te(m′, n′) of other time-series data, both are merged, and a masking start time Ts(m′, n′) and a masking end time Te(m, n) are set.

According to the present example, it is possible to eliminate a significant anomalous value caused by a rising time of a sensing-subject signal by masking signal data in a time range of a rise of a signal and a time range of a fall of the signal, and it becomes possible to execute anomaly detection of a semiconductor manufacturing apparatus stably with fewer detection errors.

In addition, according to the present example, it becomes possible to sense an anomaly of an apparatus state even in a case that a rise and a fall of a monitoring signal that correspond to the start and end of each subsequence could not be extracted accurately.

Furthermore, since the masking period creating section can set masking periods according to the present example, it becomes possible to remove the complexity of manually defining masking periods.

### Example 2

In the Example 1, a method of masking a signal rising portion and a falling portion in time-series data of a sensor signal obtained from the sensor group 800, and making a diagnosis of the apparatus state on the basis of a sensor signal that is obtained in the steady state, and the configuration related to the method have been explained. In the present example, a method of making a diagnosis of the apparatus state by also using a feature quantity of a signal in a masked portion, and the configuration related to the method will be explained. Note that constituent elements that have their counterparts in Example 1 are given the same numbers, and explanations thereof are omitted.

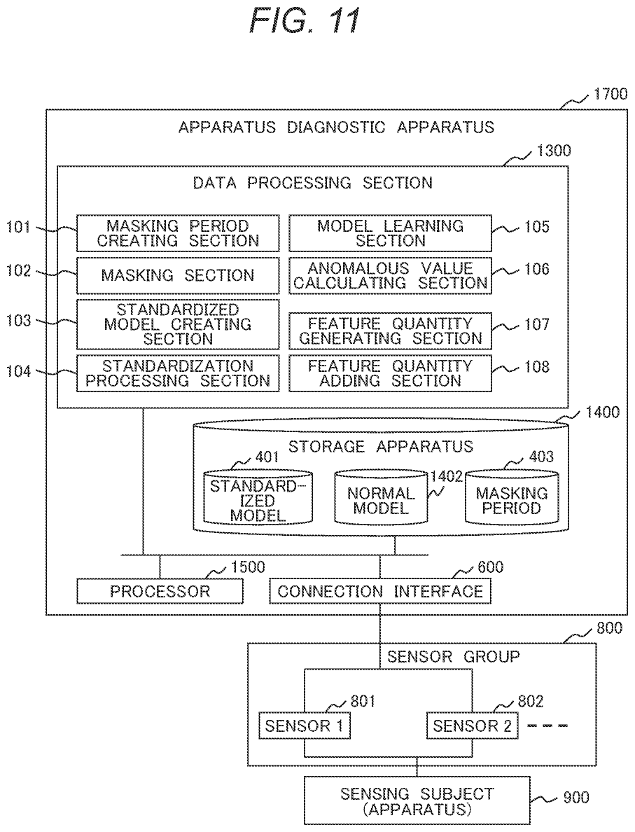

FIG. 11 depicts the relationship between an apparatus diagnostic apparatus 1700, and the sensing subject (apparatus) 900 and the sensor group 800 according to the present example. The apparatus diagnostic apparatus 1700 is different from the apparatus diagnostic apparatus 700 explained in Example 1 in that a data processing section 1300 additionally has a feature quantity generating section 107 and a feature quantity adding section 108, and also a normal model that is stored on a normal model storage section 1402 of a storage apparatus 1400 as well as a processor 1500 that controls the data processing section 1300 are different. In other respects, the configuration is the same as the one explained in Example 1.

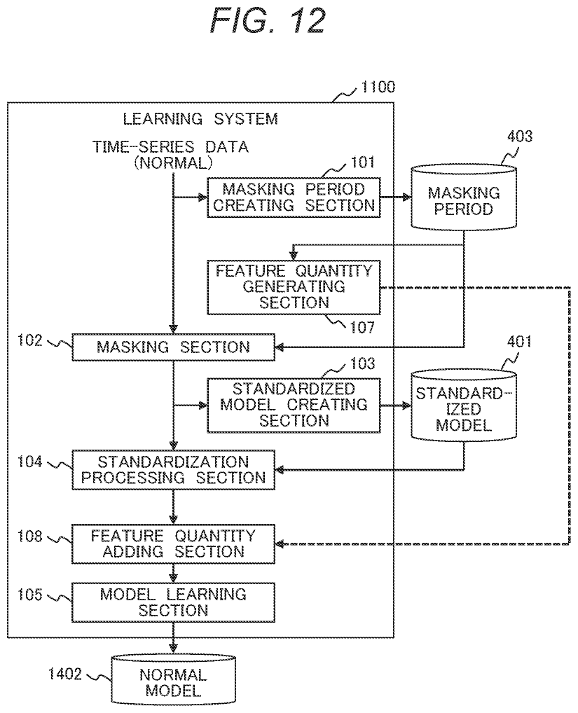

FIG. 12 depicts the configuration of a learning system 1100 in the configuration of systems each having a different functionality in the apparatus diagnostic apparatus 1700 according to the present example.

The learning system 1100 according to the present example depicted in FIG. 12 includes the masking period creating section 101, the feature quantity generating section 107, the masking section 102, the standardized model creating section 103, the standardization processing section 104, the feature quantity adding section 108, and the model learning section 105, and accepts input of time-series data that is input from the sensor group 800 via the connection interface 600, and is obtained when the sensing subject (apparatus) 900 is operating normally.

The masking period creating section 101 sets a masking period for masking some of the input time-series data, and stores it on the masking period storage section 403.

The feature quantity generating section 107 generates a feature quantity of time-series data (normal) in the masking period stored on the masking period storage section 403.

Operation of the masking section 102, the standardized model creating section 103, and the standardization processing section 104 are the same as those explained in Example 1.

The feature quantity adding section 108 adds information about the feature quantity generated at the feature quantity generating section 107 to standardized data (normal) generated at the standardization processing section 104.

The model learning section 105 learns a plurality of pieces of standardized data to which the information about the feature quantity output from the feature quantity adding section 108 is added, and stores them on the normal model storage section 1402.

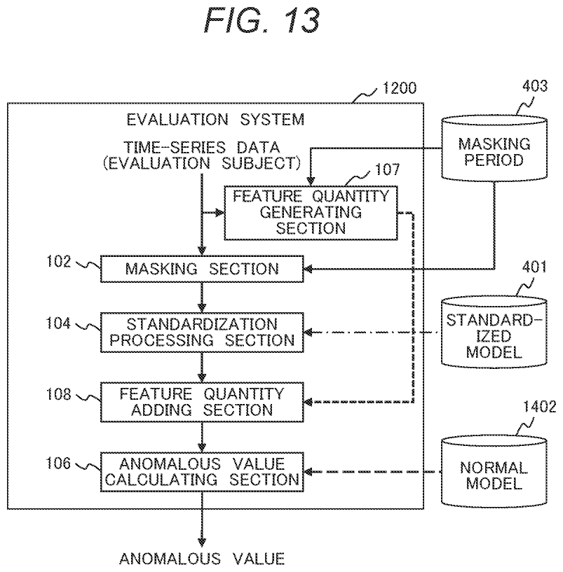

FIG. 13 depicts the configuration of an evaluation system 1200 in the configuration of systems each having a different functionality in the apparatus diagnostic apparatus 1700 according to the present example.

The evaluation system 1200 according to the present example depicted in FIG. 13 includes the feature quantity generating section 107, the masking section 102, the standardization processing section 104, the feature quantity adding section 108, and the anomalous value calculating section 106, and accepts input of time-series data that is input from the sensor group 800 via the connection interface 600, and is obtained when the sensing subject (apparatus) 900 is operating in an evaluation-subject period.

The feature quantity generating section 107 generates a feature quantity of time-series data (evaluation subject) in a masking period stored on the masking period storage section 403.

Operation of the masking section 102 and the standardization processing section 104 is the same as that explained in Example 1.

The feature quantity adding section 108 adds information about the feature quantity generated at the feature quantity generating section 107 to standardized data (normal) generated at the standardization processing section 104.

The anomalous value calculating section 106 calculates an anomalous value by comparing a plurality of pieces of the standardized data to which the information about the feature quantity output from the feature quantity adding section 108 is added with the normal model stored on the normal model storage section 1402, and outputs the detected anomalous value to an undepicted output section of the apparatus diagnostic apparatus 1700 and/or the server 960.

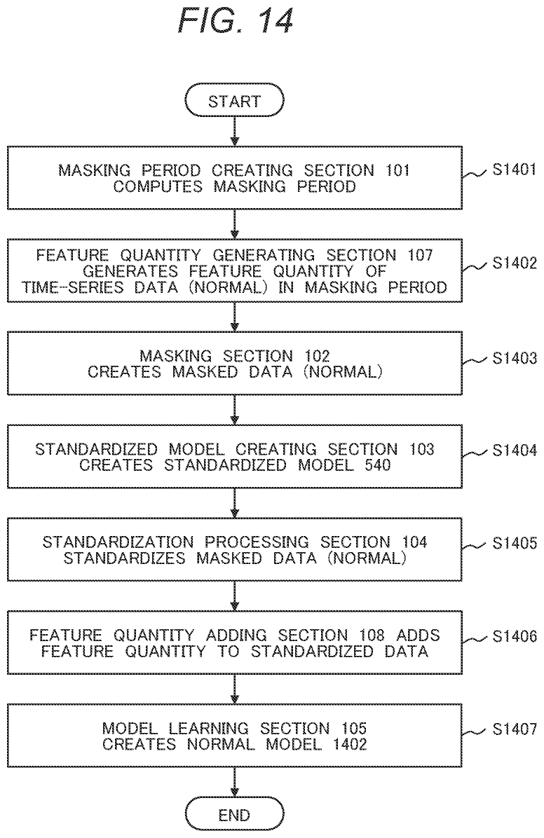

Next, a step of creating the normal model at the learning system 1100 will be explained by using FIG. 14.

S1401 in a flowchart depicted in FIG. 14 is the same as S411 in the flowchart explained by using FIG. 4 in Example 1.

At S1402, the feature quantity generating section 107 generates a feature quantity of standardized data (normal) in a masking period stored on the masking period storage section 403.

Next, S1403 to S1405 are the same as S412 to S414 in the flowchart explained by using FIG. 4 in Example 1.

At S1406, the feature quantity adding section 108 adds the feature quantity of the standardized data (normal) in the masking period generated at the feature quantity generating section 107 to the standardized data (normal) created at the standardization processing section 104.

Next, at S1407, the model learning section 105 creates a normal model by performing learning by using a plurality of pieces of data obtained by adding the feature quantity of the standardized data (normal) in the masking period generated at the feature quantity generating section 107 to the standardized data (normal) created at the standardization processing section 104 at S1406, and stores the normal model on the normal model storage section 1402.

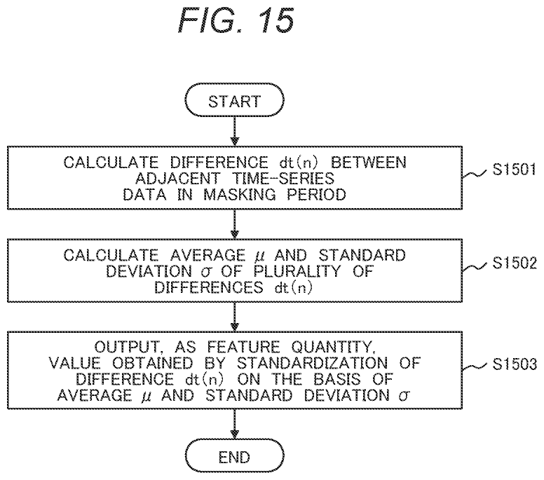

With reference to FIG. 15, a detailed procedure of processes of the step of generating the feature quantity at the feature quantity generating section 107 at S1402 in the flowchart explained in FIG. 14 will be explained.

First, a difference dt(n) between adjacent time-series data in a masking period obtained at S1401 in the process procedure in FIG. 14 is calculated sequentially (S1501).

Next, the average μ and standard deviation σ of a plurality of the calculated differences dt(n) are calculated (S1502).

Next, the difference dt(n) obtained at S1501 is standardized by using the average μ and the standard deviation σ obtained at S1502, and the standardized value is output as a feature quantity (S1503).

This output feature quantity is added to the data standardized at S1405 at S1406 in FIG. 14.

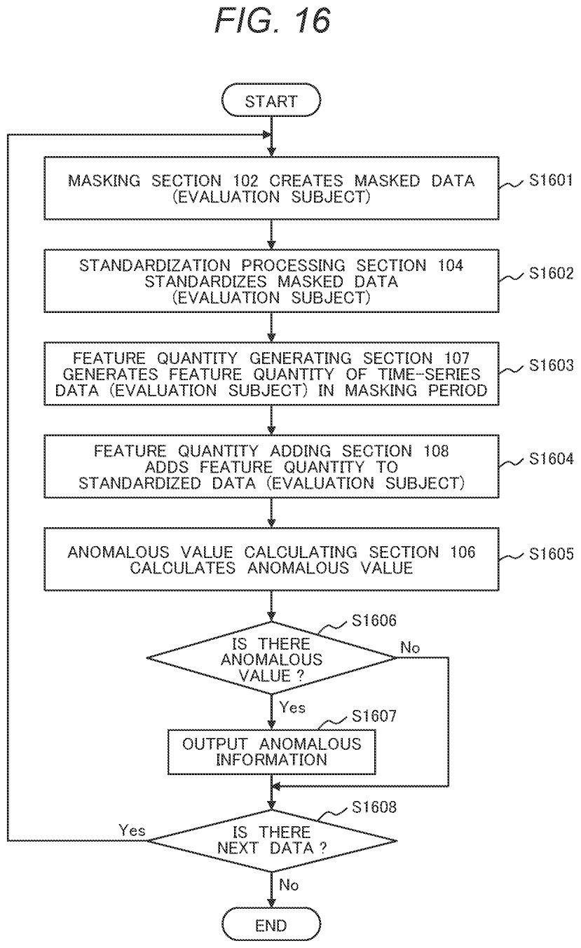

Next, a procedure of processes of detecting an anomaly by the evaluation system 200 processing time-series data that is input from the sensor group 800 via the connection interface 600, and is obtained when the sensing subject (apparatus) 900 is operating in an evaluation-subject period will be explained by using a flowchart in FIG. 16.

First, similarly to S601 explained in the flowchart in FIG. 6 in Example 1, by using data of a masking time and a masking period stored on the masking period storage section 403, the masking section 102 performs masking on evaluation-subject time-series data input from the sensor group 800 via the connection interface 600, and creates evaluation-subject masked data (S1601).

Next, similarly to S602 explained in the flowchart in FIG. 6 in Example 1, by using the standardized model stored on the standardized model storage section 401, the standardization processing section 104 performs a standardization process on the evaluation-subject masked data created at the masking section 102, and creates standardized data corresponding to the evaluation-subject time-series data (S1602).

Next, the feature quantity generating section 107 generates a feature quantity of the evaluation-subject time-series data in the masking period (S1603), and the feature quantity adding section 108 adds the generated feature quantity to the standardized data created at S1602 (S1604).

Next, the anomalous value calculating section 106 compares the evaluation-subject standardized data to which the feature quantity is added at S1604 with the normal model to which the feature quantity created at S1407 is added, and which is stored on the normal model storage section 402, and calculates an anomalous value in the evaluation-subject standardized data (S1605).

Next, it is determined whether an anomalous value is calculated at S1605 (S1606). In a case that an anomalous value is calculated (Yes at S1606), information about the anomalous value is output to the undepicted output section in the apparatus diagnostic apparatus 700 and/or the server 960 (S1607).

Next, it is checked whether there remains evaluation-subject time-series data (S1608), and in a case that there is not evaluation-subject time-series data (No at S1608), the series of processing ends. In a case that there is evaluation-subject time-series data (Yes at S1608), the procedure returns to S1601, and the series of processing is continued.

On the other hand, in a case that an anomalous value is not calculated (No at S1606), it is checked whether there remains evaluation-subject time-series data (S1608). In a case that there is not evaluation-subject time-series data (No at S1608), the series of processing ends, and in a case that there is evaluation-subject time-series data (Yes at S1608), the procedure returns to S1601, and the series of processing is continued.

According to the present example, it is possible to attain advantageous effects similar to those explained in Example 1, and since information about rise and falling portions of a sensor output signal is used further in addition to information about the steady state of the signal, an anomaly of the apparatus state or the state of a mechanism section included in the apparatus is monitored by using a larger amount of information, and thereby it becomes possible to detect an anomaly of the semiconductor manufacturing apparatus highly sensitively and stably without overlooking it.

### Example 3

In the Example 2, a method of grasping an anomaly of the apparatus state by using masked-signal rising/falling portions in evaluation-subject time-series data, and data of a signal in the steady state has been explained. In the present example, a method of grasping an anomaly of the apparatus state by using data of a signal at signal rising/falling portions in evaluation-subject time-series data without using data of a signal in the steady state will be explained.

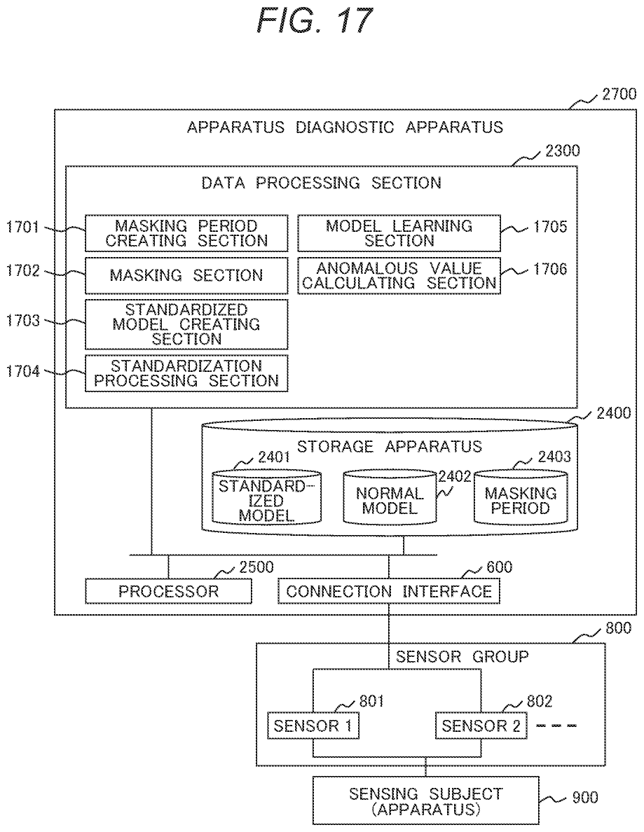

FIG. 17 depicts the relationship between an apparatus diagnostic apparatus 2700, and the sensing subject (apparatus) 900 and the sensor group 800 according to Example 3 of the present invention.

The apparatus diagnostic apparatus 2700 according to the present example is similar to the configuration of the apparatus diagnostic apparatus 700 explained by using FIG. 1 in Example 1, and processes signals obtained from the sensor group 800 including a plurality of sensors such as the sensor 1:801 (e.g. a voltage sensor), the sensor 2:802 (e.g. a pressure sensor), . . . and the like mounted on the sensing subject (apparatus) 900 such as a semiconductor manufacturing apparatus, and makes a diagnosis of the state of the sensing subject (apparatus) 900 such as the semiconductor manufacturing apparatus.

The apparatus diagnostic apparatus 2700 according to the present example includes: the connection interface 600 that receives signals output from the sensor group 800; a data processing section 2300 that processes the signals output from the sensor group 800, and input via the connection interface 600; a storage apparatus 2400 that stores data processed at the data processing section 2300; and a processor 2500 that controls processes on data at the data processing section 2300, the storage apparatus 2400, and the connection interface 600.

The data processing section 2300 includes a masking period creating section 1701, a masking section 1702, a standardized model creating section 1703, a standardization processing section 1704, a model learning section 1705, and an anomalous value calculating section 1706.

The storage apparatus 2400 includes: a standardized model storage section 2401 that stores a standardized model created at the standardized model creating section 1703 of the data processing section 2300; a normal model storage section 2402 that stores a normal model created at the model learning section 1705; and a masking period storage section 2403 that stores a masking period created at the masking period creating section 1701.

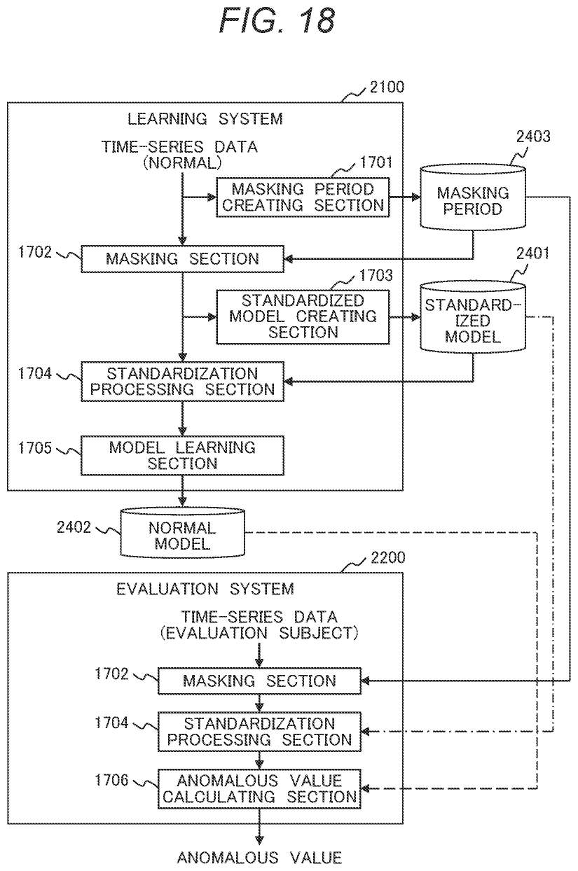

FIG. 18 depicts a block diagram depicting the configuration of systems each having a different functionality in the apparatus diagnostic apparatus 2700 according to the present example. Each section included in the data processing section 2300 in FIG. 17 is included in either a learning system 2100 or an evaluation system 2200 depending on data that it processes.

The learning system 2100 includes the masking period creating section 1701, the masking section 1702, the standardized model creating section 1703, the standardization processing section 1704, and the model learning section 1705, and accepts input of time-series data that is input from the sensor group 800 via the connection interface 600, and is obtained when the sensing subject (apparatus) 900 is operating normally.

The masking period creating section 1701 sets a masking period for masking part of the input time-series data, and stores it on the masking period storage section 2403. Here, the masked data is a signal in the steady state excluding rising/falling portions from a signal obtained from the sensor group 800, unlike the case in Example 1.

The masking section 1702 creates data in which input normal time-series data is masked, that is, time-series data of rising/falling portions of a signal obtained from the sensor group 800, on the basis of the masking data stored on masking period storage section 2403.

The standardized model creating section 1703 creates a standardized model from the data masked at the masking section 1702, and stores it on the standardized model storage section 2401. For example, in a case that sampling of rising/falling portions of a signal obtained from the sensor group 800 is performed at certain time intervals, the difference value between data of adjacent sampling periods is determined, and a standardized model obtained by standardizing the difference values is created, and stored on the standardized model storage section 2401.

By using the standardized model stored on the standardized model storage section 2401, the standardization processing section 1704 performs a standardization process on the normal-time time-series data masked at the masking section 1702 such that the average becomes 0, and the variance becomes 1, for example.

The model learning section 1705 creates a normal model by learning a plurality of pieces of standardized data created at the standardization processing section 1704 and stores the created normal model in the normal model storage section 2402.

Next, the evaluation system 2200 includes the masking section 1702, the standardization processing section 1704, and the anomalous value calculating section 1706, and accepts input of time-series data that is input from the sensor group 800 via the connection interface 600, and is obtained when the sensing subject (apparatus) 900 is operating in an evaluation-subject period.

By using data of a masking period stored on the masking period storage section 2403, the masking section 1702 performs masking on the input evaluation-subject time-series data.

By using the standardized model stored on the standardized model storage section 2401, the standardization processing section 1704 performs a standardization process on the masked time-series data such that the average becomes 0, and the variance becomes 1, for example.

The anomalous value calculating section 1706 calculates an anomalous value by comparing the data standardized at the standardization processing section 1704 with the normal model stored on the normal model storage section 402, and outputs the detected anomalous value to an undepicted output section of the apparatus diagnostic apparatus 2700 and/or the server 960.

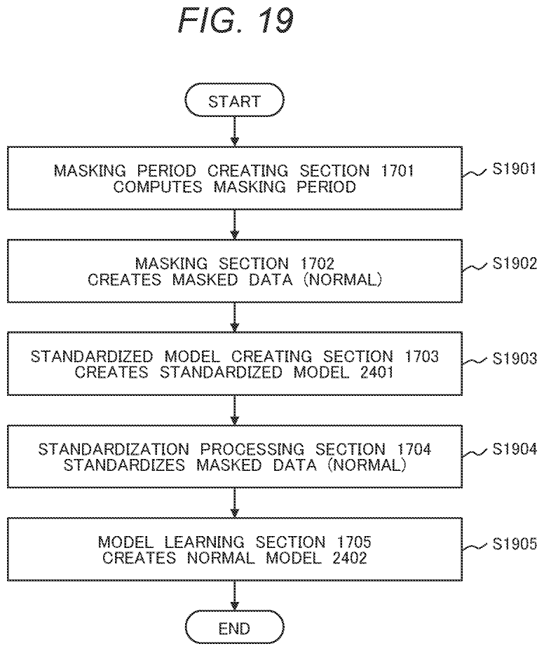

Next, a step of creating the normal model at the learning system 2100 will be explained by using FIG. 19.

First, the masking period creating section 1701 computes a masking period for masking a signal in the steady state in normal data excluding data of rising and falling periods in the signal, and stores it on the masking period storage section 2403 (S1901).

Next, on the basis of the masking data created at the masking period creating section 1701, and stored on the masking period storage section 2403, the masking section 1702 creates data obtained by masking a signal in the steady state in input normal data sandwiched by signal rising and falling portions (S1902).

Next, the standardized model creating section 1703 creates a standardized model in which the normal-time time-series data masked at the masking section 1702 has levels of the signal in the masked periods that are set to zero levels, for example, and stores it on the standardized model storage section 2401 (S1903).

Next, by using the standardized model 340 stored on the standardized model storage section 2401 and the normal-time time-series data masked at the masking section 102, the standardization processing section 1704 performs a standardization process such that the average becomes 0, and the variance becomes 1, for example, creates a pattern with a standardized signal waveform, and stores it on the model learning section 1705 (S1904).

Next, the model learning section 1705 learns a pattern with a standardized signal waveform that is obtained when the sensing subject (apparatus) is operating normally, from a plurality of patterns with standardized signal waveforms created from a plurality of pieces of normal time-series data input via the connection interface 600, and stores the pattern on the normal model storage section 2402 (S1905).

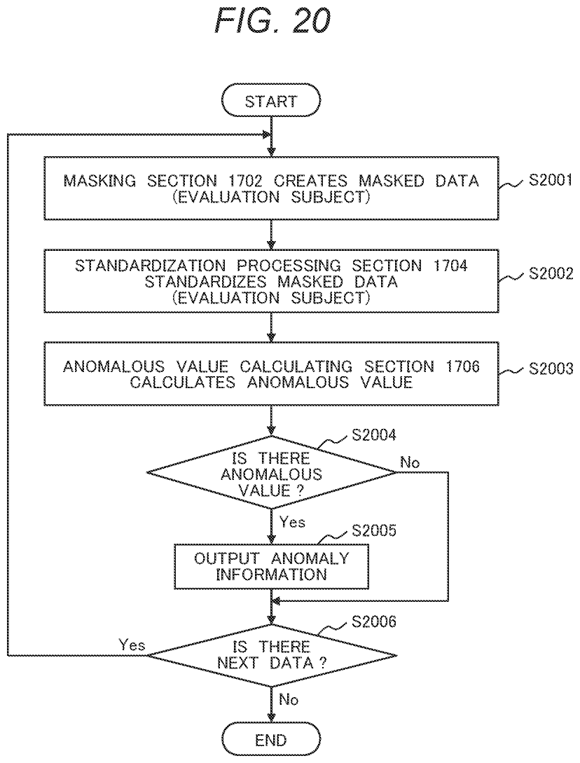

Next, a procedure of processes of detecting an anomaly by the evaluation system 2200 processing time-series data that is input from the sensor group 800 via the connection interface 600, and is obtained when the sensing subject (apparatus) 900 is operating in an evaluation-subject period will be explained by using a flowchart in FIG. 20.

First, by using data of a masking period stored on the masking period storage section 2403, the masking section 1702 performs masking on evaluation-subject time-series data input from the sensor group 800 via the connection interface 600, and creates masked data (evaluation subject) (S2001).

Next, by using the standardized model stored on the standardized model storage section 2401, the standardization processing section 1704 performs a standardization process on the masked data (evaluation subject) created at the masking section 1702, and creates standardized data (S2002).

Next, the anomalous value calculating section 1706 compares the evaluation-subject standardized data created at the standardization processing section 1704 at S2002 with the normal model stored on the normal model storage section 2402, and calculates an anomalous value in the evaluation-subject standardized data (S2003).

Next, it is determined whether an anomalous value is calculated at S2003 (S2004). In a case that an anomalous value is calculated (Yes at S2004), information about the anomalous value is output to the undepicted output section in the apparatus diagnostic apparatus 2700 and/or the server 960 (see FIG. 2) (S2005).

Next, it is checked whether there remains evaluation-subject time-series data (S2006), and in a case that there is not evaluation-subject time-series data (No at S2006), the series of processing ends. In a case that there is evaluation-subject time-series data (Yes at S2006), the procedure returns to S2001, and the series of processing is continued.

On the other hand, in a case that an anomalous value is not calculated (No at S2004), it is checked whether there remains evaluation-subject time-series data (S2006). In a case that there is not evaluation-subject time-series data (No at S2006), the series of processing ends, and in a case that there is evaluation-subject time-series data (Yes at S2006), the procedure returns to S2001, and the series of processing is continued.

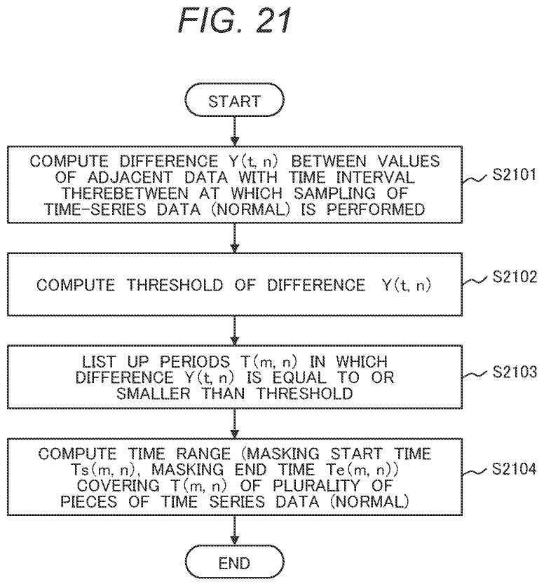

Next, a method of calculating a masking time at the masking period creating section 1701 explained regarding S1901 in FIG. 19 will be explained by using FIG. 21.

First, time-series data that is input from the sensor group 800 via the connection interface 600, and is obtained when the sensing subject (apparatus) 900 is operating normally is input to the masking period creating section 1701, sampling of the time-series data (normal) is performed at predetermined time intervals, and the difference Y(t, n) between data that is adjacent to each other with a predetermined time interval therebetween at which the sampling is performed is calculated (S2101). Here, t is a time, and n is an identifier of each of a plurality of pieces of time series data.

For example, in a case that time-series data like that depicted in FIG. 8 explained in Example 1 is input, since the time-series data exhibits gradual changes between the times t₁ and t₂ corresponding to a rising portion 811 of a signal, and between the times t₃ and t₄ corresponding to a falling portion 812 of the signal, the difference Y(t, n) between values of adjacent data has finite values greater than zero. On the other hand, since the signal 810 between the times t₂ and t₃ is almost constant, the difference Y(t, n) between values of adjacent time-series data is zero or a value close to zero.

Next, a threshold of the difference Y(t, n) is computed by using a plurality of pieces of time series data (S2102). For example, a value obtained by multiplying the standard deviation σ of a plurality of differences Y(t, n) by N is defined as the threshold. Here, regarding time-series data like that depicted in FIG. 8, the threshold is set to a value greater than the difference Y(t, n) between values of adjacent time-series data in the signal 810 between the times t₂ and t₃, and smaller than the difference Y(t, n) between values of time-series data between the times t₁ and t₂ and between the times t₃ and t₄.

Next, periods T(m, n) in which the difference Y(t, n) calculated at S2101 becomes equal to or smaller than the threshold set at S2102 are listed up (S2103).

In the Example 1, as has been depicted in the table 910 in FIG. 9, the masking start time 912 is set to the time t₁ or t₃ in the sensor-value time-series data in FIG. 8, and the masking end time 913 is set to the time t₂ or t₄ in the sensor-value time-series data in FIG. 8. In the present example, the masking start time will be set to t₂ in FIG. 8 at which the sensor-value time-series data has risen, and enters the steady state, and the masking end time is set to t₃ in FIG. 8 at which the sensor-value time-series data starts falling from the steady state.

Next, a time range (the masking start time Ts(m, n), and the masking end time Te(m, n)) that cover periods T(m, n) during which the difference Y(t, n) becomes equal to or smaller than the threshold that are listed up at S2103 is computed (S2104). By setting the masking start time Ts(m, n) and the masking end time Te(m, n) such that they cover the periods T(m, n) during which the difference Y(t, n) becomes equal to or smaller than the threshold that are listed up at S2103 in this manner, it becomes possible to surely mask the time range during which the signal is in the steady state even if time-series data (evaluation subject) includes small variations, and the reliability of monitoring of the apparatus state can be enhanced due to information about a rising portion and a falling portion of the signal.

Finally, information about the masking start time Ts(m, n) and the masking end time Te(m, n) that are determined by the computation at S2104 is sent from the masking period creating section 1701 to the masking period storage section 2403, and the step of computing the masking period at S1901 is ended.

Since, according to the present example, the apparatus state can be monitored by using information reflected in rising and falling portions of a sensor output signal in a case that an anomaly of the apparatus state is to be grasped, even in a case that a rise and a fall of a monitoring signal corresponding to the start and end of each subsequence could not be extracted accurately, it becomes possible to detect an anomaly of the semiconductor manufacturing apparatus stably without overlooking it in a case that an anomaly of the apparatus state or the mechanism section included in the apparatus is observed in a rising or falling portion of the sensor output signal.

### Example 4

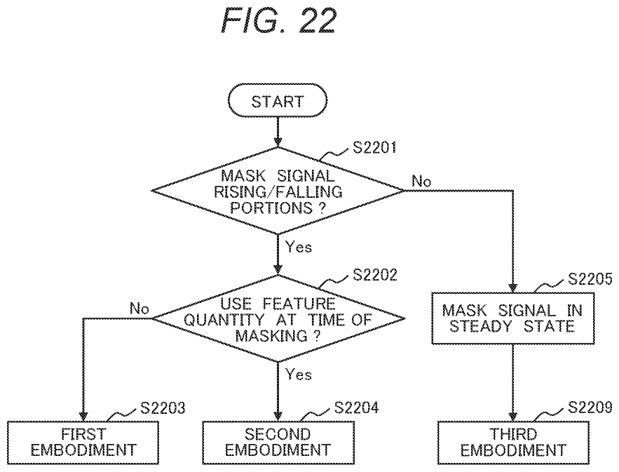

Example 4 of the present invention will be explained by using FIG. 22.

The present example is a combination of Examples 1 to 3 explained above, and the apparatus state monitoring methods are used on a case-by-case basis in accordance with the characteristics of a monitoring-subject apparatus or the characteristics of signals detected by monitoring-subject sensors.

That is, in the present example, the apparatus state monitoring methods explained in Examples 1 to 3 described above are used on a case-by-case basis depending on whether it is a case that an anomalous state of the monitoring-subject apparatus is likely to be reflected in data in the steady state of signals from sensors, a case that an anomalous state of the monitoring-subject apparatus is likely to be reflected also in data of a signal rise/fall in addition to the steady state of the signals, or a case that an anomalous state of the monitoring-subject apparatus is likely to be reflected in data of a signal rise/fall.

That is, in the present example, in a case that an anomalous state of the monitoring-subject apparatus is likely to be reflected in data in the steady state of signals from sensors, a rising portion and a falling portion of a signal from the sensors are masked, and an anomaly of the monitoring-subject apparatus is detected by using only data in the steady state of signals from the sensors. In addition, in a case that an anomalous state of the monitoring-subject apparatus is likely to be reflected also in data of a signal rise/fall in addition to the steady state of the signal, a rising portion and a falling portion of a signal from sensors are set as masking areas, and an anomaly of the monitoring-subject apparatus is detected by using a feature quantity of signals of the rising portion and the falling portion of the signals from the sensors in these masking areas, and data of the steady state of signals from the sensors. Furthermore, in a case that an anomalous state of the monitoring-subject apparatus is likely to be reflected in data of a signal rise/fall, the area of the steady state of the signals is masked, and an anomaly of the monitoring-subject apparatus is detected by using data of the signal rise/fall.

This may be applied to the sensing subject (apparatus) 900 as a whole, or the methods explained in Examples 1 to 3 may be used on a case-by-case basis for each output signal from an individual sensor included in the sensor group 800 attached to each mechanism section included in the sensing subject (apparatus) 900.

First, it is determined whether to or not to mask signal rising/falling portions of time-series data of sensor values (signals) that are input from the sensor group 800, and obtained when the sensing subject (apparatus) 900 is operating (S2201).

In a case that the signal rising/falling portions are to be masked (Yes at S2201), the procedure proceeds to S2202, and it is determined whether to or not to use feature quantities of the signal at a time of masking. In a case that feature quantities of the signal at a time of masking are not to be used, the procedure proceeds to S2203, and an anomaly of the apparatus state is detected by the procedure explained in Example 1. On the other hand, in a case that feature quantities of the signal at a time of masking are to be used, the procedure proceeds to S2204, and an anomaly of the apparatus state is detected by the procedure explained in Example 2.

In a case that it is determined at S2201 that the signal rising/falling portions are not to be masked (No at S2201), the procedure proceeds to S2205, the signal in the steady state is masked, the procedure proceeds to S2206, and an anomaly of the apparatus state is detected by the procedure explained in Example 3.

According to the present example, a diagnostic method can be selected in accordance with the characteristics of an inspection-subject sensor output signal corresponding to an inspection-subject apparatus or a mechanism section included in the apparatus, and the advantageous effects respectively explained in Examples 1 to 3 can be attained by making a diagnosis of the apparatus state highly sensitively by using signals suited for the inspection-subject apparatus or the mechanism section included in the apparatus.

Although the invention made by the present inventors has been explained specifically thus far on the basis of examples, it is needless to say that the present invention is not limited to those examples, and can be changed variously within the scope not departing from its aim. For example, the examples described above are explained in detail in order to explain the present invention in an easy-to-understand manner, and are not necessarily limited to those including all the constituent elements explained. In addition, some of the constituent elements of each example can additionally have other constituent elements, can be eliminated or replaced with other constituent elements.

### REFERENCE SIGNS LIST

100, 1100, 2100 . . . learning system
101, 1701 . . . masking period creating section
102, 1702 . . . masking section
103, 1703 . . . standardized model creating section
104, 1704 . . . standardization processing section
105, 1705 . . . model learning section
106, 1706 . . . anomalous value calculating section
200, 1200, 2200 . . . evaluation system
300, 1300, 2300 . . . data processing section
400 . . . storage apparatus
401, 2401 . . . standardized model storage section
402, 2402 . . . normal model storage section
403, 2403 . . . masking period storage section
500, 2500 . . . processor
600 . . . connection interface
700, 1700, 2700 . . . apparatus diagnostic apparatus
800 . . . sensor group
900 . . . sensing subject (apparatus)

1. A diagnostic apparatus that makes a diagnosis of a state of a semiconductor manufacturing apparatus by using first time-series data acquired from a sensor group of the semiconductor manufacturing apparatus,
wherein a masking period including a rising time of the first time-series data or a falling time of the first time-series data is determined,
the first time-series data of the determined masking period is converted into a predetermined value, and also the converted first time-series data is output as second time-series data, and
the diagnosis of the state of the semiconductor manufacturing apparatus is made on the basis of the second time-series data.

2. The diagnostic apparatus according to claim 1,
wherein the masking period is a time at which a difference of the first time-series data between adjacent sampling times becomes greater than a standard deviation of the difference.

3. A diagnostic apparatus that makes a diagnosis of a state of a semiconductor manufacturing apparatus by using first time-series data acquired from a sensor group of the semiconductor manufacturing apparatus,
wherein a masking period including a rising time of the first time-series data or a falling time of the first time-series data is determined,
the first time-series data of the determined masking period is converted into a predetermined value, and also a feature quantity of the masking period is determined,
the converted first time-series data is output as second time-series data,
the determined feature quantity is added to the second time-series data, and
the diagnosis of the state of the semiconductor manufacturing apparatus is made on the basis of the second time-series data to which the feature quantity is added.

4. The diagnostic apparatus according to claim 3,
wherein the feature quantity is determined on the basis of a time difference between a time at which a first difference becomes greater than a standard deviation of the first difference and a time at which a second difference becomes greater than a standard deviation of the second difference,
the first difference is a difference of the first time-series data between adjacent sampling times, and
the second difference is a difference of reference time-series data between adjacent sampling times.

5. (canceled)

6. A semiconductor manufacturing apparatus system,
wherein a semiconductor manufacturing apparatus is connected via a network, and includes the diagnostic apparatus according to claim 1.

7. A semiconductor manufacturing apparatus system,
wherein a semiconductor manufacturing apparatus is connected via a network, and includes the diagnostic apparatus according to claim 3.

8. A semiconductor manufacturing apparatus system,
wherein a semiconductor manufacturing apparatus is connected via a network, and includes the diagnostic apparatus according to claim 5.

9. The semiconductor manufacturing apparatus system according to claim 6,
wherein the diagnostic apparatus is a personal computer.

10. A semiconductor apparatus manufacturing system comprising a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network,
wherein the application executes:
a step at which a masking period including a rising time of the first time-series data or a falling time of the first time-series data is determined;
a step at which the first time-series data of the determined masking period is converted into a predetermined value, and also the converted first time-series data is output as second time-series data; and
a step at which the diagnosis of the state of the semiconductor manufacturing apparatus is made on the basis of the second time-series data.

11. A semiconductor apparatus manufacturing system comprising a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network,
wherein the application executes:
a step at which a masking period including a rising time of the first time-series data or a falling time of the first time-series data is determined;
a step at which the first time-series data of the determined masking period is converted into a predetermined value, and also a feature quantity of the masking period is determined;
a step at which the converted first time-series data is output as second time-series data;
a step at which the determined feature quantity is added to the second time-series data; and
a step at which the diagnosis of the state of the semiconductor manufacturing apparatus is made on the basis of the second time-series data to which the feature quantity is added.

12. A semiconductor apparatus manufacturing system comprising a platform that implements an application for making a diagnosis of a state of a semiconductor manufacturing apparatus by using first time-series data acquired from a sensor group of the semiconductor manufacturing apparatus, and to which the semiconductor manufacturing apparatus is connected via a network,
wherein the application executes:
a step at which a masking period including a rising time of the first time-series data or a falling time of the first time-series data is determined;
a step at which the first time-series data of the determined masking period is converted into a predetermined value, and also a feature quantity of the masking period is determined; and
a step at which the diagnosis of the state of the semiconductor manufacturing apparatus is made on the basis of the feature quantity.

13. A diagnostic method of making a diagnosis of a state of a semiconductor manufacturing apparatus by using first time-series data acquired from a sensor group of the semiconductor manufacturing apparatus, the diagnostic method comprising:
a step at which a masking period including a rising time of the first time-series data or a falling time of the first time-series data is determined;
a step at which the first time-series data of the determined masking period is converted into a predetermined value, and also the converted first time-series data is output as second time-series data; and
a step at which the diagnosis of the state of the semiconductor manufacturing apparatus is made on the basis of the second time-series data.

14. A diagnostic method of making a diagnosis of a state of a semiconductor manufacturing apparatus by using first time-series data acquired from a sensor group of the semiconductor manufacturing apparatus, the diagnostic method comprising:
a step at which a masking period including a rising time of the first time-series data or a falling time of the first time-series data is determined;
a step at which the first time-series data of the determined masking period is converted into a predetermined value, and also a feature quantity of the masking period is determined;
a step at which the converted first time-series data is output as second time-series data;
a step at which the determined feature quantity is added to the second time-series data; and
a step at which the diagnosis of the state of the semiconductor manufacturing apparatus is made on the basis of the second time-series data to which the feature quantity is added.

15. (canceled)
